(19) United States
(12) Patent Application Publication
(10) Pub. No.: US 2025/0192003 A1
(43) Pub. Date: Jun. 12, 2025

(54) BACKSIDE CONTACT EXTENSION FOR STACKED FIELD EFFECT TRANSISTOR

(71) Applicant: International Business Machines Corporation, Armonk, NY (US)

(72) Inventors: Ruilong Xie, Niskayuna, NY (US); Chen Zhang, Santa Clara, CA (US); Shahrukh Khan, Sandy Hook, CT (US); Junli Wang, Slingerlands, NY (US)

(21) Appl. No.: 18/531,912

(22) Filed: Dec. 7, 2023

(51) Int. Cl. H01L 23/48; H01L 21/8238; H01L 25/07; H01L 27/092; H01L 29/06; H01L 29/417; H01L 29/423; H01L 29/66; H01L 29/775; H01L 29/786

(52) U.S. Cl. CPC H01L 23/481; H01L 25/074; H10D 30/014; H10D 30/43; H10D 30/6729; H10D 30/6735; H10D 30/6757; H10D 62/121; H10D 84/017; H10D 84/0188; H10D 84/038; H10D 84/85

(57) ABSTRACT

A semiconductor device is provided and includes a first transistor including a first source/drain (S/D) region, a second transistor stacked over the first transistor and including a second S/D region, a first backside power rail (BPR) disposed below the first transistor, a second BPR disposed below the first BPR, a via by which the second S/D region and the first BPR are connected and metallization. The metallization passes through and is insulated from the first BPR. The first S/D region and the second BPR are connected by the metallization.

### BACKGROUND

The present invention generally relates to fabrication methods and resulting structures for semiconductor devices. More specifically, the present invention relates to a backside contact extension for a stacked field effect transistor (SFET).

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each interconnect becomes increasingly significant.

### SUMMARY

According to an aspect of the disclosure, a semiconductor device is provided. The semiconductor device includes a first transistor including a first source/drain (S/D) region, a second transistor stacked over the first transistor and including a second S/D region, a first backside power rail (BPR) disposed below the first transistor, a second BPR disposed below the first BPR, a via by which the second S/D region and the first BPR are connected and metallization, which passes through and is insulated from the first BPR, and by which the first S/D region and the second BPR are connected. In additional or alternative embodiments, the semiconductor device is provided as a stacked field effect transistor (SFET) that includes a backside contact that extends beyond an edge of an active region to connect a bottom S/D region to a frontside interconnect through a deep via.

According to an aspect of the disclosure, a semiconductor device is provided and includes multiple stacked field effect transistors (SFETs), each including a bottom FET including a bottom source/drain (S/D) region and a top FET stacked over the bottom FET and including a top S/D region, a first backside power rail (BPR) disposed below the bottom FET of each of the multiple SFETs, a second BPR disposed below the first BPR, a via by which the top S/D region of one of the multiple SFETs and the first BPR are connected and metallization, which passes through and is insulated from the first BPR, and by which the bottom S/D region of the one of the multiple SFETs and the second BPR are connected. In additional or alternative embodiments, the semiconductor device is provided as a stacked field effect transistor (SFET) that includes a backside contact that extends beyond an edge of an active region to connect a bottom S/D region to a frontside interconnect through a deep via.

According to an aspect of the disclosure, a method of forming a semiconductor device is provided and includes forming placeholders under locations at which source/drain (S/D) regions of bottom transistors of transistor stacks are to be assembled, forming first and second vias into shallow trench isolation (STI) between neighboring placeholders, executing a wafer flip and substrate removal, executing backside contact extension patterning to form an opening between one of the placeholders and the first via, replacing the placeholders with backside contacts, a first one of which extends through the opening to the first via, recessing the backside contacts and the first via, connecting a first backside power rail (BPR) to the second via and connecting a second BPR to a second one of the backside contacts via metallization which is isolated from the first BPR. In additional or alternative embodiments, the semiconductor device is provided as a stacked field effect transistor (SFET) that includes a backside contact that extends beyond an edge of an active region to connect a bottom S/D region to a frontside interconnect through a deep via.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A and 1B are side and plan views, respectively, of a semiconductor device according to one or more embodiments of the present invention;

FIG. 2A is a flow diagram illustrating a method of semiconductor device fabrication including timed etching in accordance with one or more embodiments of the present invention;

FIG. 2B is a flow diagram illustrating a method of semiconductor device fabrication including etching that stops at an etch stop layer in accordance with one or more embodiments of the present invention;

FIG. 3 is a top-down view of a semiconductor device assembly being fabricated in accordance with one or more embodiments of the present invention;

FIG. 4 is a side view of a semiconductor device assembly at an initial stage of assembly taken along line “Y2” of FIG. 3 in accordance with one or more embodiments of the present invention;

FIG. 5 is a side view of a semiconductor device assembly at a secondary stage of assembly taken along line “Y2” of FIG. 3 in accordance with one or more embodiments of the present invention;

FIG. 6 is a side view of a semiconductor device assembly at a third stage of assembly taken along line “Y2” of FIG. 3 in accordance with one or more embodiments of the present invention;

FIG. 7 is a side view of a semiconductor device assembly at a fourth stage of assembly taken along line “Y2” of FIG. 3 in accordance with one or more embodiments of the present invention;

FIG. 8 is a side view of a semiconductor device assembly at a fifth stage of assembly taken along line “Y2” of FIG. 3 in accordance with one or more embodiments of the present invention;

FIG. 9 is a side view of a semiconductor device assembly at a sixth stage of assembly taken along line “Y2” of FIG. 3 in accordance with one or more embodiments of the present invention;

FIG. 10 is a side view of a semiconductor device assembly at a seventh stage of assembly taken along line “Y2” of FIG. 3 in accordance with one or more embodiments of the present invention;

FIG. 11 is a side view of a semiconductor device assembly at an eighth stage of assembly taken along line “Y2” of FIG. 3 in accordance with one or more embodiments of the present invention;

FIG. 12 is a side view of a semiconductor device assembly at a ninth stage of assembly taken along line “Y2” of FIG. 3 in accordance with one or more embodiments of the present invention;

FIG. 13 is a side view of a semiconductor device assembly including an etch stop layer at an initial stage of assembly taken along line “Y2” of FIG. 3 in accordance with one or more embodiments of the present invention; and

FIG. 14 is a side view of a semiconductor device assembly in which an opening is formed to the etch stop layer of FIG. 13 at a seventh stage of assembly taken along line “Y2” of FIG. 3 in accordance with one or more embodiments of the present invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

According to an aspect of the disclosure, a semiconductor device is provided. The semiconductor device includes a first transistor including a first source/drain (S/D) region, a second transistor stacked over the first transistor and including a second S/D region, a first backside power rail (BPR) disposed below the first transistor, a second BPR disposed below the first BPR, a via by which the second S/D region and the first BPR are connected and metallization, which passes through and is insulated from the first BPR, and by which the first S/D region and the second BPR are connected. In additional or alternative embodiments, the semiconductor device is provided as a stacked field effect transistor (SFET) that includes a backside contact that extends beyond an edge of an active region to connect a bottom S/D region to a frontside interconnect through a deep via.

The first and second transistors form a first stacked field effect transistor (SFET) according to a complementary-metal-oxide-semiconductor (CMOS) compatible process.

The semiconductor device further includes a second SFET including an additional first transistor comprising an additional first S/D region, an additional second transistor stacked over the additional first transistor and comprising an additional second S/D region and additional metallization, which passes through and is insulated from the first BPR, and by which the additional first S/D region and the second BPR are connected. The semiconductor device further includes dielectric spacers disposed along the metallization and the additional metallization to insulate the metallization and the additional metallization from the first BPR. The dielectric spacers allow for the first and second BPR to avoid short circuits.

The first and second BPRs are two-dimensional (2D) plates or planar features and, as such, extend continuously.

The semiconductor device further includes a frontside contact by which the via is connected to the second S/D region and a backside contact by which the metallization is connected to the first S/D region according to a complementary-metal-oxide-semiconductor (CMOS) compatible process.

The semiconductor device further includes another backside contact and a dielectric cap self-aligned to and configured to insulate the another backside contact from the first BPR according to a complementary-metal-oxide-semiconductor (CMOS) compatible process.

The semiconductor device further includes an etch stop layer disposed to delimit a height of a portion of an upper surface of the another backside contact. The etch stop layer allows for etching to be stopped without need for timing the etching.

The semiconductor device further includes a carrier wafer, a back-end-of-line (BEOL) layer interposed between the carrier wafer and the second transistor and a plurality of additional frontside vias by which other first and second S/D regions are connected to the BEOL layer according to a complementary-metal-oxide-semiconductor (CMOS) compatible process.

According to an aspect of the disclosure, a semiconductor device is provided and includes multiple stacked field effect transistors (SFETs), each including a bottom FET including a bottom source/drain (S/D) region and a top FET stacked over the bottom FET and including a top S/D region, a first backside power rail (BPR) disposed below the bottom FET of each of the multiple SFETs, a second BPR disposed below the first BPR, a via by which the top S/D region of one of the multiple SFETs and the first BPR are connected and metallization, which passes through and is insulated from the first BPR, and by which the bottom S/D region of the one of the multiple SFETs and the second BPR are connected. In additional or alternative embodiments, the semiconductor device is provided as a stacked field effect transistor (SFET) that includes a backside contact that extends beyond an edge of an active region to connect a bottom S/D region to a frontside interconnect through a deep via.

The semiconductor device further includes additional metallization, which passes through and is insulated from the first BPR, and by which the bottom S/D region of a second one of the multiple SFETs and the second BPR are connected and dielectric spacers disposed along the metallization and the additional metallization to insulate the metallization and the additional metallization from the first BPR. The dielectric spacers allow for the first and second BPR to avoid short circuits.

The first and second BPRs are two-dimensional (2D) plates or planar features and, as such, extend continuously.

The semiconductor device further includes a frontside contact by which the via is connected to the top S/D region of the one of the multiple SFETs and a backside contact by which the metallization is connected to the bottom S/D region of the one of the multiple SFETs according to a complementary-metal-oxide-semiconductor (CMOS) compatible process.

The semiconductor device further includes another backside contact of another one of the multiple SFETs and a dielectric cap to insulate the another backside contact from the first BPR according to a complementary-metal-oxide-semiconductor (CMOS) compatible process.

The semiconductor device further includes an etch stop layer disposed to delimit a height of a portion of an upper surface of the another backside contact. The etch stop layer allows for etching to be stopped without need for timing the etching.

The semiconductor device further includes a carrier wafer, a back-end-of-line (BEOL) layer interposed between the carrier wafer and the top FET of each of the multiple SFETs and a plurality of additional frontside vias by which top and bottom S/D regions of other ones of the multiple stack FETs are connected to the BEOL layer according to a complementary-metal-oxide-semiconductor (CMOS) compatible process.

According to an aspect of the disclosure, a method of forming a semiconductor device is provided and includes forming placeholders under locations at which source/drain (S/D) regions of bottom transistors of transistor stacks are to be assembled, forming first and second vias into shallow trench isolation (STI) between neighboring placeholders, executing a wafer flip and substrate removal, executing backside contact extension patterning to form an opening between one of the placeholders and the first via, replacing the placeholders with backside contacts, a first one of which extends through the opening to the first via, recessing the backside contacts and the first via, connecting a first backside power rail (BPR) to the second via and connecting a second BPR to a second one of the backside contacts via metallization which is isolated from the first BPR. In additional or alternative embodiments, the semiconductor device is provided as a stacked field effect transistor (SFET) that includes a backside contact that extends beyond an edge of an active region to connect a bottom S/D region to a frontside interconnect through a deep via.

The method further includes interposing a dielectric cap between the first one of the backside contacts and the first BPR according to a complementary-metal-oxide-semiconductor (CMOS) compatible process.

The method further includes connecting the second BPR to an additional one of the backside contacts via additional metallization which is isolated from the first BPR according to a complementary-metal-oxide-semiconductor (CMOS) compatible process.

The executing of the backside contact extension patterning includes timed etching of the STI at a location of the opening. The timed etching prevents the etching from removing material in an undesirable manner.

The executing of the backside contact extension patterning includes disposing an etch stop layer on the STI and etching the STI at a location of the opening to the etch stop layer. The etch stop layer allows for etching to be stopped without need for timing the etching.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, an SFET can be formed by stacking at least one transistor over another one. By doing so, the footprint needed for both transistors is reduced as compared to conventional transistor layout where all devices are laid out at the same level.

A backside power rail (BPR) refers to power rails that are buried below the transistors, or at a backside of the transistors. Backside power distribution networks (BSPDNs), or grids, enable scaling beyond 5 nm with the back side being below the transistor substrate. BPR technology enables the freeing up of resources for dense logic connections often limiting modern processor performance. Further scaling of a standard logic cell is enabled by removing overhead in areas occupied by power rails. Finally, thicker low-resistance power rails are allowed, which enable lower voltage (IR) drops.

For SFETs, it is often hard to form a backside contact that extends beyond an edge of an active region to connect a bottom source/drain (S/D) to a frontside interconnect through a deep via. This is because backside contact placeholder formation is usually confined within the active region. Also, it can be challenging to form BPRs to both bottom FETs and top FETs without creating or risking short circuits.

Turning now to an overview of the aspects of the invention, one or more embodiments of the invention address the above-described shortcomings of the prior art by providing a semiconductor device includes a first transistor and a second transistor. The first transistor includes a first S/D region. The second transistor is stacked over the first transistor and includes a second S/D region. The semiconductor device further includes a first BPR disposed below the first transistor, a second BPR disposed below the first BPR, a via by which the second S/D region and the first BPR are connected and metallization, which passes through and is insulated from the first BPR, and by which the first S/D region and the second BPR are connected.

The above-described aspects of the invention address the shortcomings of the prior art by providing for a semiconductor device structure that is provided as an SFET. The SFET includes a backside contact that extends beyond an edge of an active region to connect a bottom S/D region to a frontside interconnect through a deep via.

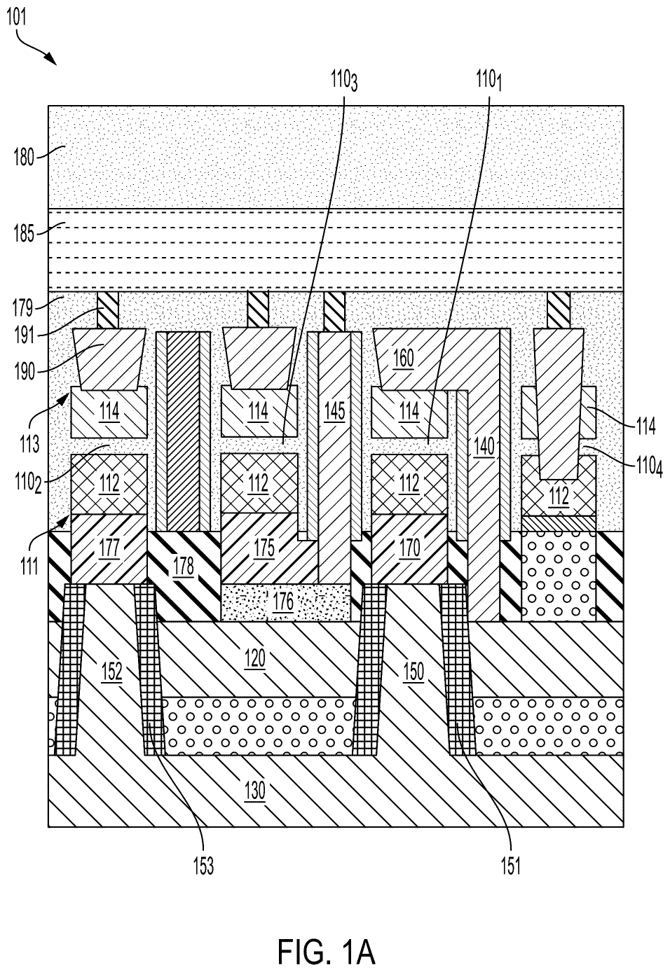

Turning now to a more detailed description of aspects of the present invention, FIGS. 1A and 1B depict a semiconductor device 101. The semiconductor device 101 includes multiple SFETs 110₁₋₄. Each of the multiple SFETs 110₁₋₄ includes a bottom FET 111 including a bottom S/D region 112 and a top FET 113 stacked over the bottom FET 111 and including a top S/D region 114. The semiconductor device 101 further includes a first BPR 120 (or backside power plate, or backside power plane) that is disposed below the bottom FET 111 of each of the multiple SFETs 110₁₋₄, a second BPR 130 that is disposed below the first BPR 120, a first deep via 140 by which the top S/D region 114 of a first one of the multiple SFETs 110₁ and the first BPR 120 are connected, a second deep via 145 and metallization 150. The metallization 150 passes through and is insulated from the first BPR 120 by dielectric spacers 151. The bottom S/D region 112 of the first one of the multiple SFETs 110₁ and the second BPR 130 are connected by way of the metallization 150.

In addition, the semiconductor device 101 includes additional metallization 152, a frontside contact 160, a backside contact 170, another backside contact 175 and a dielectric cap 176. The additional metallization 152 passes through and is insulated from the first BPR 120 by additional dielectric spacers 153. The bottom S/D region 112 of a second one of the multiple SFETs 110₂ and the second BPR 130 are connected by way of the additional metallization 152 and an additional backside contact 177. The first deep via 140 is connected to the top S/D region 114 of the one of the multiple SFETs 110₁ by way of the frontside contact 160. The metallization 150 is connected to the bottom S/D region 112 of the one of the multiple SFETs 110₁ by way of the backside contact 170. The second deep via 145 and the bottom S/D region 112 of a third one of the multiple SFETs 1103 are connected by way of the another backside contact 175. The dielectric cap 176 insulates the another backside contact 175 from the first BPR 120. The dielectric cap 176 can include a low-k dielectric material (i.e., a lower-k dielectric material than shallow trench isolation (STI) 178 and can be self-aligned to the another backside contact 175.

The semiconductor device 101 can also include a carrier wafer 180, a BEOL layer 185 that is interposed between the carrier wafer 180 and the top FET 113 of each of the multiple SFETs 110₁₋₄ and the surrounding interlayer dielectric (ILD) 179 and a plurality of additional frontside contacts 190 with frontside vias (V0) 191 by which the top S/D regions 114 of the second, third and fourth ones of the multiple SFETs 110₂₋₄, are connected to the BEOL layer 185 and by which the bottom S/D region 112 of the second one of the multiple stack FETs 110₂ is connected to the BEOL layer 185 by way of the another backside contact 175 and the second deep via 145.

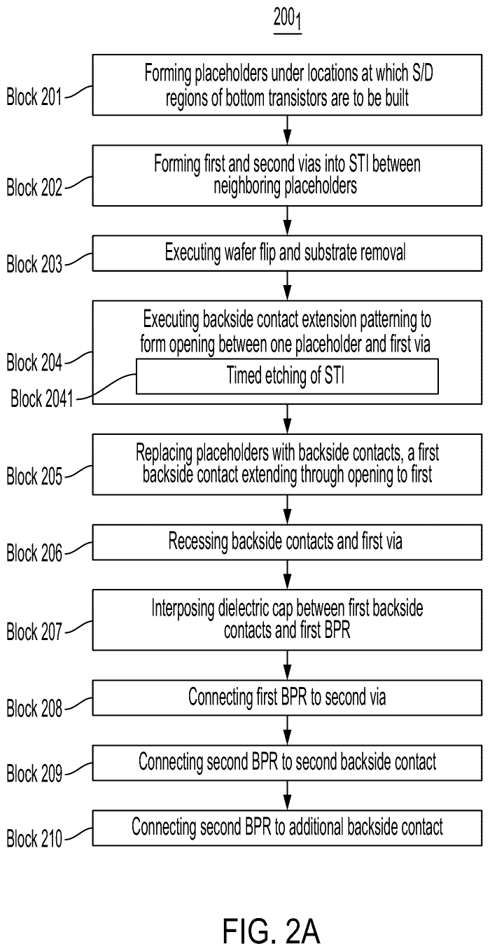

In accordance with embodiments, the first BPR 120 and the second BPR 130 can be provided as planar or plate-like features that extend continuously in a plane (i.e., the combined X-Y planes of FIG. 3, see below)

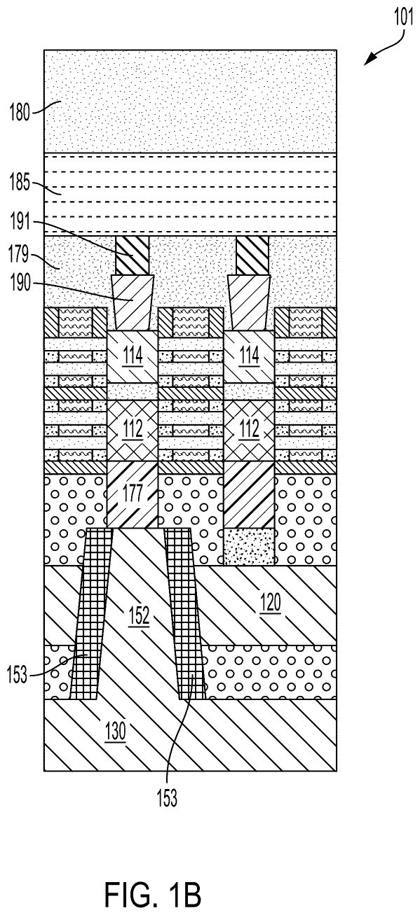

With reference to FIGS. 2A and 2B, methods 2001 and 2002 of forming a semiconductor device, such as the semiconductor device 101 of FIGS. 1A and 1B, are provided. Each of the methods 2001 and 2002 includes forming placeholders under locations at which S/D regions of bottom transistors of transistor stacks, such as SFETs, are to be built (block 201), forming first and second vias into shallow trench isolation (STI) between neighboring placeholders (block 202), executing a wafer flip and substrate removal (block 203), executing backside contact extension patterning to form an opening between one of the placeholders and the first via (block 204), replacing the placeholders with backside contacts, a first one of which extends through the opening to the first via (block 205), recessing the backside contacts and the first via (block 206), connecting a first BPR to the second via (block 208) and connecting a second BPR to a second one of the backside contacts via metallization which is isolated from the first BPR (block 209). The method 200 can also include interposing a dielectric cap between the first one of the backside contacts and the first BPR (block 207) and connecting the second BPR to an additional one of the backside contacts via additional metallization which is isolated from the first BPR (block 210).

As shown in FIG. 2A, the executing of the backside contact extension patterning of block 204 can include timed etching of the STI at a location of the opening (block 2041). As shown in FIG. 2B, the executing of the backside contact extension patterning of block 204 can include disposing an etch stop layer on the STI (block 2042) and etching the STI at a location of the opening to the etch stop layer (block 2043).

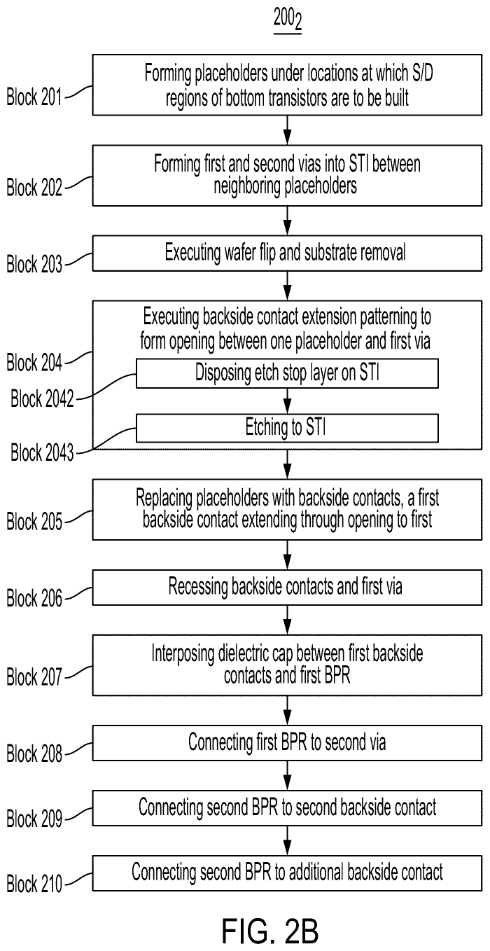

With continued reference to FIGS. 1A and 1B and to FIG. 2 and with additional reference to FIG. 3 and to FIGS. 4-12 and FIGS. 13 and 14, the method 200 of FIG. 2 will now be described in greater detail.

FIG. 3 depicts a top-down view of a semiconductor device assembly 301 that is being fabricated. The semiconductor device assembly 301 includes first-fourth active regions 310₁₋₄, and first, second and third gates 320₁₋₃ extending across the first-fourth active regions 310₁₋₄. For reference, FIG. 1A, FIGS. 4-12 and FIGS. 13 and 14 are taken along the view defined by the line “Y2” of FIG. 3 and FIG. 1B is taken along the view defined by the line “X” of FIG. 3.

As shown in FIG. 4, a semiconductor device assembly 401 is provided in an initial stage of assembly following dummy gate formation. The semiconductor device assembly 401 includes a semiconductor substrate 410, an etch stop layer 420 disposed on the semiconductor substrate 410 and a semiconductor layer 430 disposed on the etch stop layer 420. The semiconductor layer 430 is formed to define pedestals with STI 440 provided between neighboring pedestals. Stacks 450 of various layers of semiconductor material (i.e., SiGe60, SiGe30 and Si) are disposed on each of the pedestals.

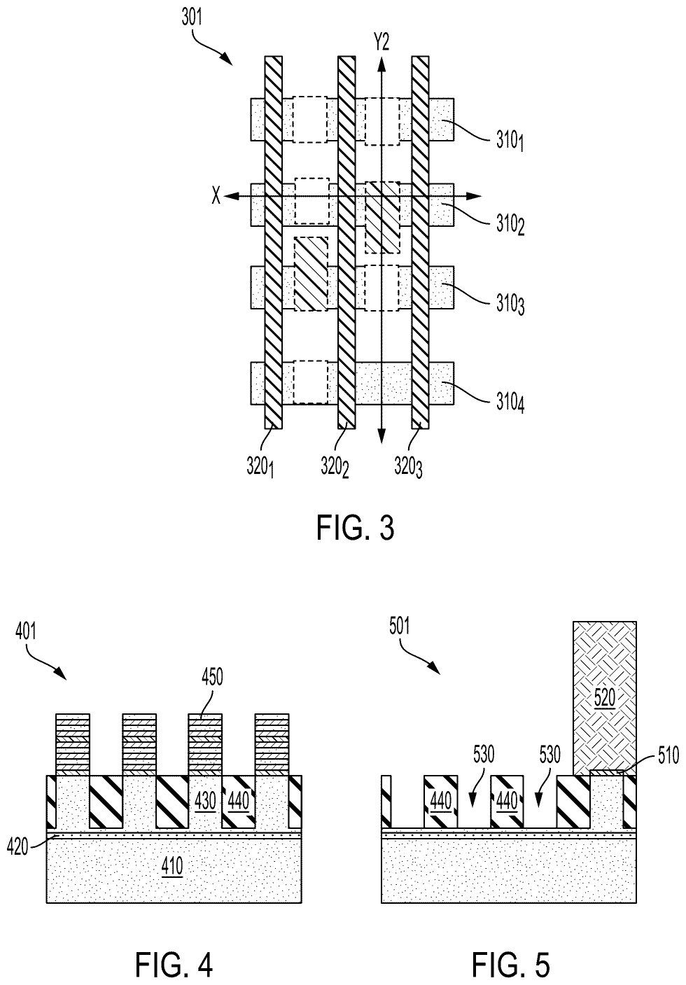

As shown in FIG. 5, a semiconductor device assembly 501 is provided in a secondary stage of assembly following SiGe60 removal, formations of gate spacers (not shown), bottom dielectric (BDI) 510 and middle dielectric isolation (MD) (not shown) and inner spacer formation (not shown) as well as placeholder patterning applied with respect to the semiconductor device assembly 401 of FIG. 4. The semiconductor device assembly 501 includes the BDI 510 disposed on one of the pedestals and a mask 520 disposed over and around the BDI 510. With the mask 520 being present, the unmasked pedestals can be removed between the STI 440 to create placeholder openings 530.

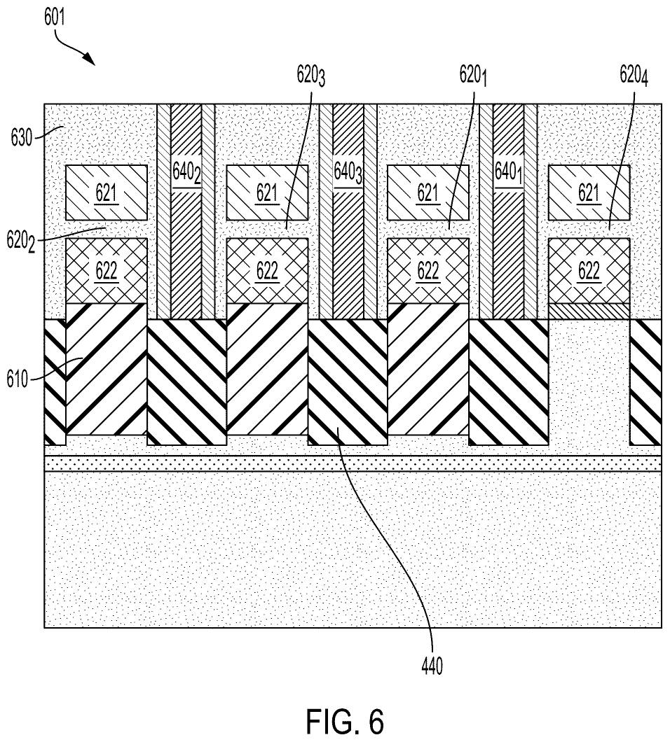

As shown in FIG. 6, a semiconductor device assembly 601 is provided in a third stage of assembly following formation of placeholders 610 in the placeholder openings 530 of FIG. 5, execution of S/D epitaxy, ILD formation, dummy gate and SiGe removal, replacement high-k metal gate formation, gate cut patterning and bi-layer gate cut filling applied with respect to the semiconductor device assembly 501 of FIG. 5. By the execution of the S/D epitaxy, the semiconductor device assembly 601 includes multiple SFETs 620₁₋₄, each of which includes top epitaxy forming a top S/D region 621 and bottom epitaxy forming a bottom S/D region 622, ILD 630 and bi-layer gate cut elements 640₁₋₃. The ILD formation forms the ILD 630 to surround each of the multiple SFETs 620₁₋₄. The gate cut patterning form openings through the ILD 630 to the STI 440 and the bi-layer gate cut filling forms the bi-layer gate cut elements 640₁₋₃ to fill the openings. Each of the bi-layer gate cut elements 640₁₋₃ can include a first dielectric, such as SiN, surrounding a second dielectric, such as SiO2.

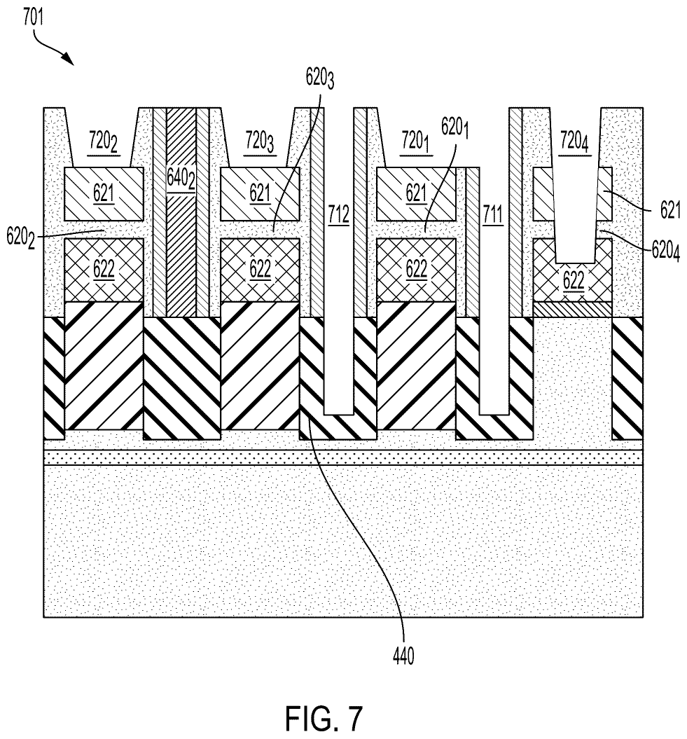

As shown in FIG. 7, a semiconductor device assembly 701 is provided in a fourth stage of assembly following self-aligned deep via patterning and contact (CA/CB) patterning applied with respect to the semiconductor device assembly 601 of FIG. 6. Execution of the self-aligned deep via patterning results in partial removal of bi-layer gate cut elements 640_{1, 3} of FIG. 6, formation of first deep via opening 711 and second deep via opening 712 into and partially through STI 440 and preserves bi-layer gate cut element 640₂. The contact patterning results in the formation of contact openings 720₁₋₄. Contact opening 720₁ extends to the top S/D region 621 of a first one of the multiple SFETs 620₁ and the first deep via opening 711. Contact openings 720_{2, 3} extend to the top S/D regions 621 of second and third ones of the multiple SFETs 620_{2, 3}, respectively. Contact opening 720₄ extends through the top S/D region 621 and into the bottom S/D region 622 of a fourth one of the multiple SFETs 620₄.

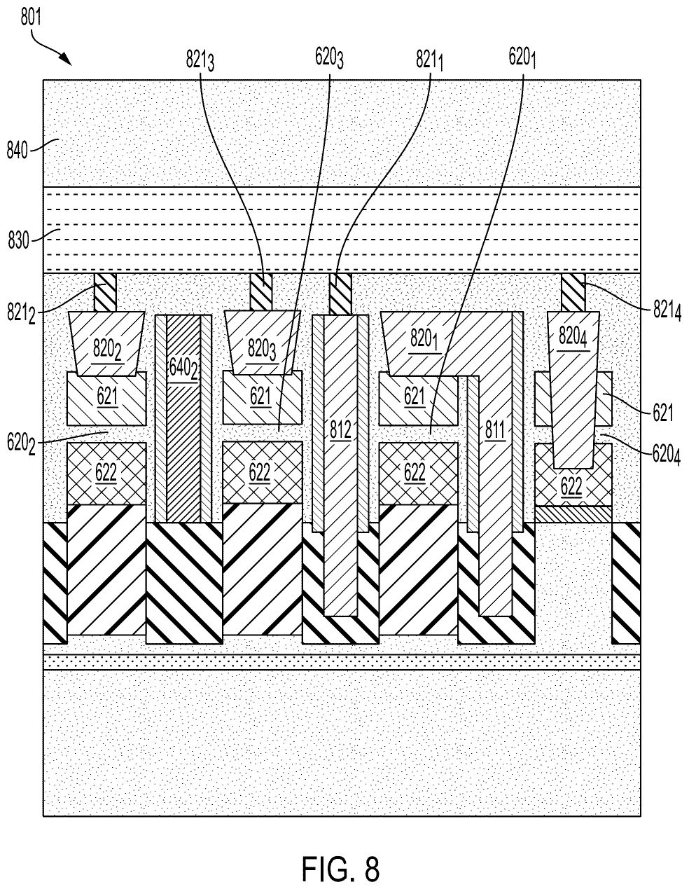

As shown in FIG. 8, a semiconductor device assembly 801 is provided in a fifth stage of assembly following middle-of-line (MOL) metallization to form first deep via 811 and second deep via 812 as well as frontside contacts 820₁₋₄ in the contact openings 720₁₋₄ of FIG. 7 and frontside contact extensions 821₁₋₄ (through an additional layer of ILD), BEOL formation to form BEOL layer 830 and carrier wafer bonding to form carrier wafer 840 applied with respect to the semiconductor device assembly 701 of FIG. 7. Frontside contact 820₁ fills the contact opening 720₁ of FIG. 7 and contacts the top S/D region 621 of the first one of the multiple SFETs 620₁ and the first deep via 811. Frontside via (V0) 821₁ connects the second deep via 812 to the BEOL layer 830. V0 820₂ fills the contact opening 720₂ of FIG. 7 and contacts the top S/D region 621 of the second one of the multiple SFETs 620₂ whereby the frontside contact 820₂ and the V0 821₂ connect the top S/D region 621 of the second one of the multiple SFETs 620₂ to the BEOL layer 830. Frontside contact 820₃ fills the contact opening 720₃ of FIG. 7 and contacts the top S/D region 621 of the third one of the multiple SFETs 620₃ whereby the frontside contact 820₃ and the frontside contact extension 8213 connect the top S/D region 621 of the third one of the multiple SFETs 620₃ to the BEOL layer 830. Frontside contact 820₄ fills the contact opening 720₄ of FIG. 7 and contacts the top and bottom S/D regions 621 and 622 of the fourth one of the multiple SFETs 620₄ whereby the frontside contact 820₄ and the V0 821₄ connect the top and bottom S/D regions 621 and 622 of the fourth one of the multiple SFETs 620₄ to the BEOL layer 830.

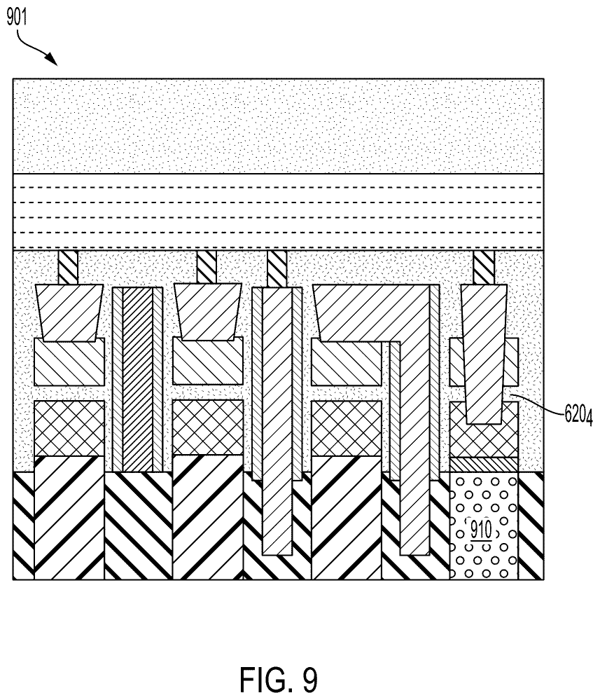

As shown in FIG. 9, a semiconductor device assembly 901 is provided in a sixth stage of assembly following wafer flip, substrate removal by etching that stops at the etch stop layer 420 of FIG. 4, removal of the etch stop layer 420 of FIG. 4, removal of the semiconductor layer 430 of FIG. 4, backside ILD deposition and chemical mechanical polishing (CMP) applied with respect to the semiconductor device assembly 801 of FIG. 8. The removal of the semiconductor layer 430 of FIG. 4 results in the removal of the remaining pedestal below the fourth one of the multiple SFETs 620₄ and the backside ILD deposition results in the formation of backside ILD element 910.

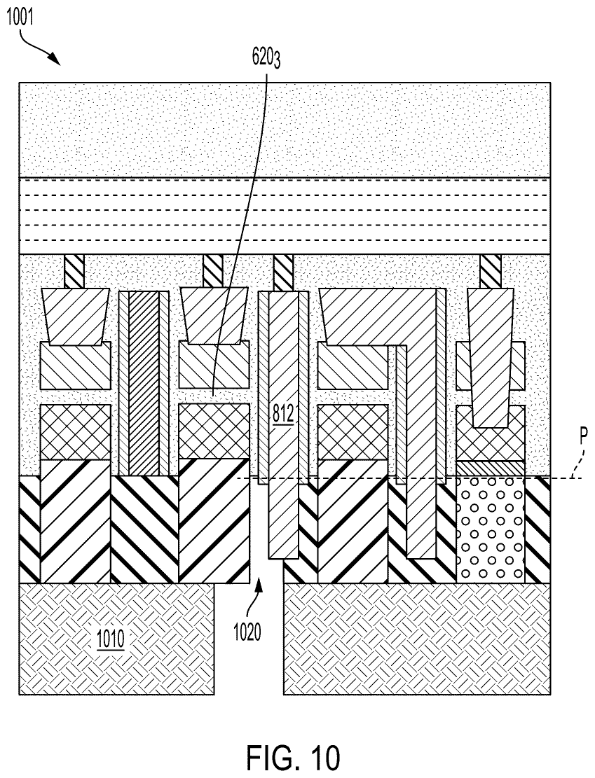

As shown in FIG. 10, a semiconductor device assembly 1001 is provided in a seventh stage of assembly following backside contact extension patterning and etching applied with respect to the semiconductor device assembly 901 of FIG. 9. The etching in the one or more embodiments of the present invention of FIG. 10 can be timed so as to stop at plane P. The semiconductor device assembly 1001 thus includes OPL 1010 and defines, as a result of the etching, an opening 1020 through the OPL 1010 and between the placeholder below the third one of the multiple SFETs 620₃ and the second deep via 812.

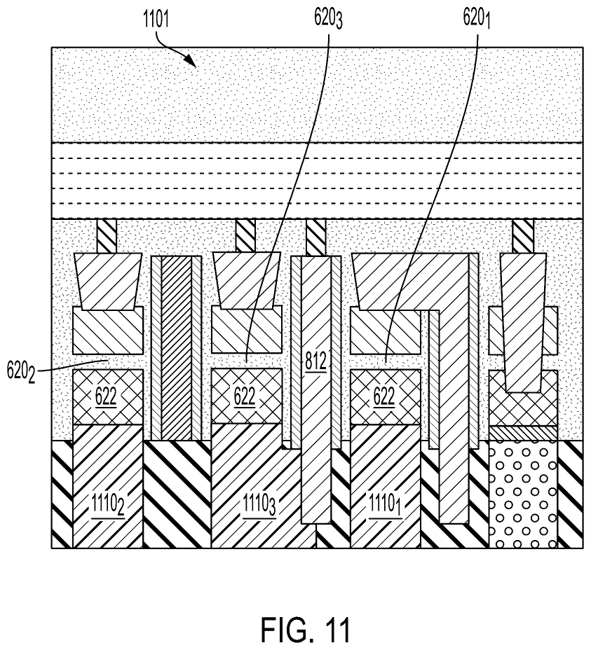

As shown in FIG. 11, a semiconductor device assembly 110₁ is provided in an eighth stage of assembly following placeholder removal and backside contact metallization applied with respect to the semiconductor device assembly 1001 of FIG. 10. The placeholder removal and the backside contact metallization result in the removal of the OPL 1010 of FIG. 10 and the effective replacement of the remaining placeholders with backside contacts 1110₁₋₃. Backside contact 1110₁ contacts the bottom S/D region 622 of the first one of the multiple SFETs 620₁. Backside contact 1110₂ contacts the bottom S/D region 622 of the second one of the multiple SFETs 620₂. Backside contact 1110₃ contacts the bottom S/D region 622 of the third one of the multiple SFETs 620₃ and the second deep via 812.

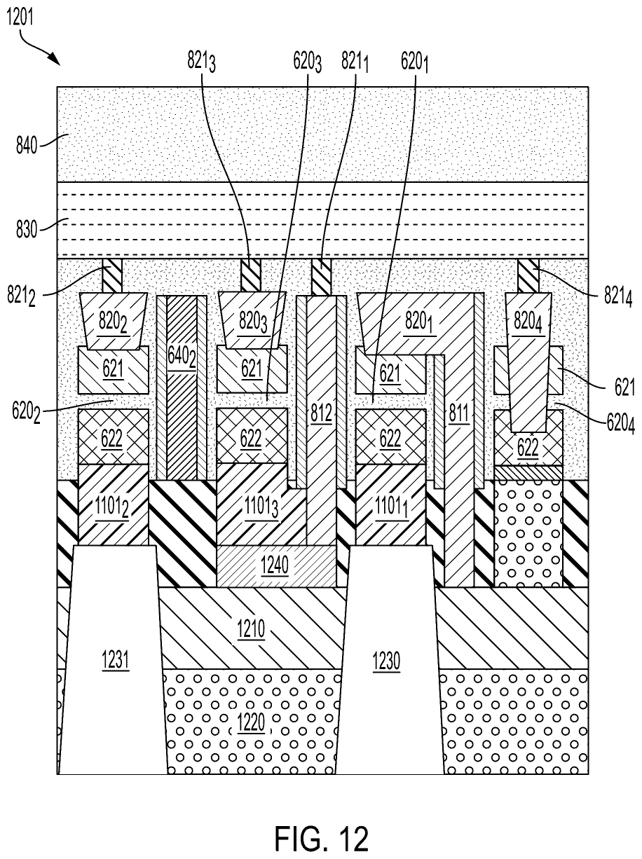

As shown in FIG. 12, a semiconductor device assembly 1201 is provided in a ninth stage of assembly following backside contact recess using a mask to only recess backside contact 1110₃, dielectric cap formation and CMP, formation of first BPR (or a 2D backside power plate or backside power plane) 1210, deposition of ILD 1220 and formation of via 1230 and additional via 1231 applied with respect to the semiconductor device assembly 110₁ of FIG. 11. The backside contact recess recesses backside contact 1110₃ and the second deep via 812 by conventional lithography and etching process. The dielectric cap formation forms dielectric cap 1240 over exposed portions of the backside contact 1110₃ and the second deep via 812. The dielectric cap 1240 can be self-aligned to the backside contact 1110₃ and the second deep via 812 and can be but does not need to be formed of a low-k dielectric material (i.e., a lower-k dielectric material than the STI 440 of FIG. 4) or any other suitable dielectric material. The first BPR 1210 extends across the exposed portions of the STI 440 and the dielectric cap 1240 and the ILD 1220 extends over the first BPR 1210. The via 1230 extends through the ILD 1220 and the first BPR 1210 to the backside contact 1110₁ and the additional via 1231 extends through the ILD 1220 and the first BPR 1210 to the backside contact 1110₂.

With reference back to FIG. 1, the semiconductor device 101 is formed as a final stage of assembly following dielectric formation (i.e., to form the dielectric spacers 151 and the additional dielectric spacers 153) and metallization (i.e., to form the metallization 150, the additional metallization 152 and the second BPR 130 application with respect to the semiconductor device assembly 1201 of FIG. 12.

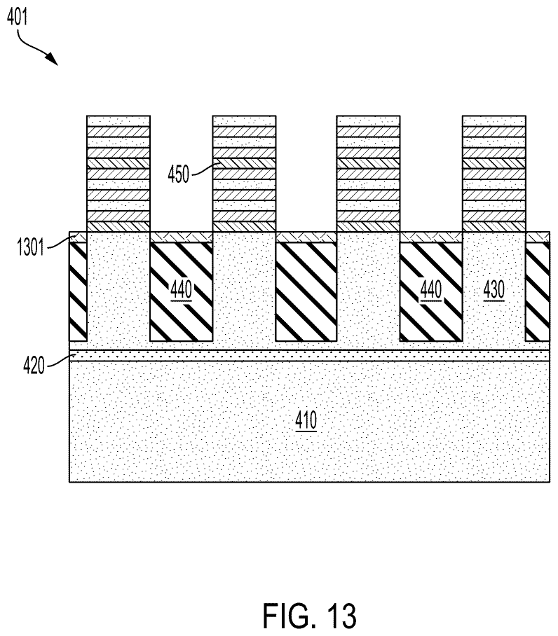

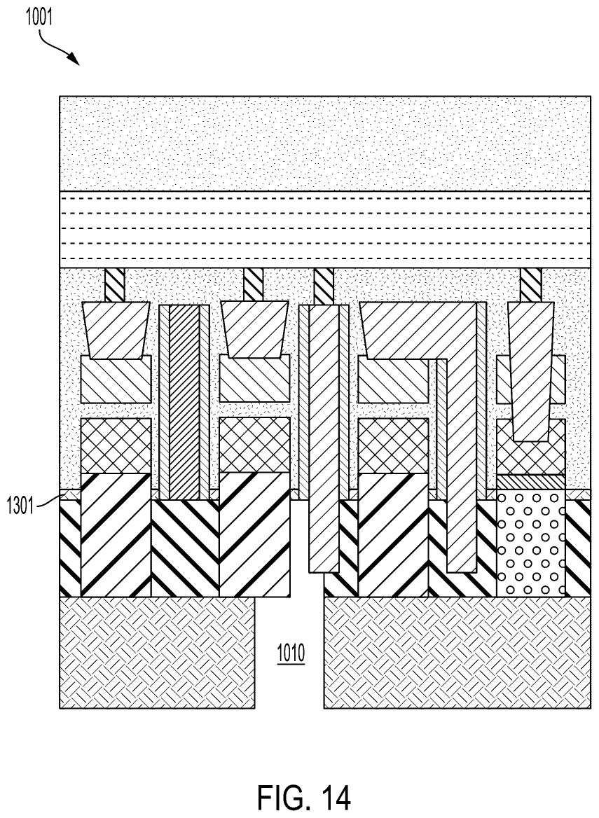

With reference to FIGS. 13 and 14 and in accordance with one or more alternative embodiments of the present invention, an etch stop layer 1301 can be disposed on the STI 440 of FIG. 4 (see FIG. 13) whereby the etching to form the opening 1020 of FIG. 10 stops at the etch stop layer 1301 (see FIG. 14) and effectively sets or delimits a height of a portion of an upper surface of the backside contact 1110₃.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device, comprising:
a first transistor comprising a first source/drain (S/D) region;
a second transistor stacked over the first transistor and comprising a second S/D region;
a first backside power rail (BPR) disposed below the first transistor;
a second BPR disposed below the first BPR;
a via by which the second S/D region and the first BPR are connected; and
metallization, which passes through and is insulated from the first BPR, and by which the first S/D region and the second BPR are connected.

2. The semiconductor device according to claim 1, wherein the first and second transistors form a first stacked field effect transistor (SFET).

3. The semiconductor device according to claim 2, further comprising a second SFET comprising:
an additional first transistor comprising an additional first S/D region;
an additional second transistor stacked over the additional first transistor and comprising an additional second S/D region; and
additional metallization, which passes through and is insulated from the first BPR, and by which the additional first S/D region and the second BPR are connected,
wherein the semiconductor device further comprises dielectric spacers disposed along the metallization and the additional metallization to insulate the metallization and the additional metallization from the first BPR.

4. The semiconductor device according to claim 1, wherein the first and second BPRs are two-dimensional (2D) plates or planar features.

5. The semiconductor device according to claim 1, further comprising:
a frontside contact by which the via is connected to the second S/D region; and
a backside contact by which the metallization is connected to the first S/D region.

6. The semiconductor device according to claim 5, further comprising:
another backside contact; and
a dielectric cap self-aligned to and configured to insulate the another backside contact from the first BPR.

7. The semiconductor device according to claim 6, further comprising an etch stop layer disposed to delimit a height of a portion of an upper surface of the another backside contact.

8. The semiconductor device according to claim 1, further comprising:
a carrier wafer;
a back-end-of-line (BEOL) layer interposed between the carrier wafer and the second transistor; and
a plurality of additional frontside vias by which other first and second S/D regions are connected to the BEOL layer.

9. A semiconductor device, comprising:
multiple stacked field effect transistors (SFETs), each comprising:
a bottom FET comprising a bottom source/drain (S/D) region; and
a top FET stacked over the bottom FET and comprising a top S/D region;
a first backside power rail (BPR) disposed below the bottom FET of each of the multiple SFETs;
a second BPR disposed below the first BPR;
a via by which the top S/D region of one of the multiple SFETs and the first BPR are connected; and
metallization, which passes through and is insulated from the first BPR, and by which the bottom S/D region of the one of the multiple SFETs and the second BPR are connected.

10. The semiconductor device according to claim 9, further comprising:
additional metallization, which passes through and is insulated from the first BPR, and by which the bottom S/D region of a second one of the multiple SFETs and the second BPR are connected; and
dielectric spacers disposed along the metallization and the additional metallization to insulate the metallization and the additional metallization from the first BPR.

11. The semiconductor device according to claim 9, wherein the first and second BPRs are two-dimensional (2D) plates or planar features.

12. The semiconductor device according to claim 9, further comprising:
a frontside contact by which the via is connected to the top S/D region of the one of the multiple SFETs; and
a backside contact by which the metallization is connected to the bottom S/D region of the one of the multiple SFETs.

13. The semiconductor device according to claim 12, further comprising:
another backside contact of another one of the multiple SFETs; and
a dielectric cap to insulate the another backside contact from the first BPR.

14. The semiconductor device according to claim 13, further comprising an etch stop layer disposed to delimit a height of a portion of an upper surface of the another backside contact.

15. The semiconductor device according to claim 9, further comprising:
a carrier wafer;
a back-end-of-line (BEOL) layer interposed between the carrier wafer and the top FET of each of the multiple SFETs; and
a plurality of additional frontside vias by which top and bottom S/D regions of other ones of the multiple stack FETs are connected to the BEOL layer.

16. A method of forming a semiconductor device, the method comprising:
forming placeholders under locations at which source/drain (S/D) regions of bottom transistors of transistor stacks are to be assembled;
forming first and second vias into shallow trench isolation (STI) between neighboring placeholders;
executing a wafer flip and substrate removal;
executing backside contact extension patterning to form an opening between one of the placeholders and the first via;
replacing the placeholders with backside contacts, a first one of which extends through the opening to the first via;
recessing the backside contacts and the first via;
connecting a first backside power rail (BPR) to the second via; and
connecting a second BPR to a second one of the backside contacts via metallization which is isolated from the first BPR.

17. The method according to claim 16, further comprising interposing a dielectric cap between the first one of the backside contacts and the first BPR.

18. The method according to claim 16, further comprising connecting the second BPR to an additional one of the backside contacts via additional metallization which is isolated from the first BPR.

19. The method according to claim 16, wherein the executing of the backside contact extension patterning comprises timed etching of the STI at a location of the opening.

20. The method according to claim 16, wherein the executing of the backside contact extension patterning comprises:
disposing an etch stop layer on the STI; and
etching the STI at a location of the opening to the etch stop layer.
